(19) United States
(12) Patent Application Publication
(10) Pub. No.: US 2007/0141842 A1
(43) Pub. Date: Jun. 21, 2007

(54) Method of Manufacturing Semiconductor Device

(75) Inventors: Whee Won Cho, Cheongju-si (KR); Jung Geun Kim, Seoul (KR); Sang Deok Kim, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/427,559

(22) Filed: Jun. 29, 2006

(30) Foreign Application Priority Data
Dec. 20, 2005 (KR) 10-2005-0126161

(51) Int. Cl. H01L 21/302; H01L 21/461

(52) U.S. Cl. 438/689

(57) ABSTRACT

Disclosed herein is a method of manufacturing a semiconductor device. The method includes forming an etch-stop film on a semiconductor substrate in which a predetermined structure is formed, and then forming an interlayer insulating film. The method also includes etching a predetermined region of the interlayer insulating film, and then stopping the etch process at the etch-stop film, to form a damascene pattern. The method employs an etch-stop film made of a material having a low dielectric constant. Accordingly, an increase in the capacitance due to an etch-stop film formed of the existing material having a high dielectric constant can be prevented. It is therefore possible to prevent a reduction of RC delay and also to accelerate the operating speed of devices.

### BACKGROUND OF THE INVENTION

1. Field of the Disclosure

The present invention generally relates to a method of manufacturing semiconductor devices, and more particularly, to a method of manufacturing semiconductor devices, in which when trenches and a via hole are formed by patterning an interlayer insulating film using a damascene process, a material with a low dielectric constant is used as an etch-stop film, thereby preventing an increase in the capacitance.

2. Brief Description of Related Technology

An alloy of tungsten and aluminum is used as the metal lines of the semiconductor devices. As the level of integration of the semiconductor devices is increased, the tungsten and aluminum alloy has a high resistivity and a poor reliability due to electro migration or stress migration.

To solve the problems, copper having a low resistivity and a good reliability has emerged as the material of the metal lines. However, copper is difficult to etch by a general etch process. Accordingly, after an interlayer insulating film is formed, a via hole for forming a plug and trenches for forming lines are formed. A dual damascene process for burying copper is performed to form copper lines.

To form the via hole and the trenches by etching the interlayer insulating film, an etch-stop film that functions to stop the etching of the interlayer insulating film must be formed below the interlayer insulating film. A material having an etch selectivity different from that of the interlayer insulating film is used as the etch-stop film. For example, because the interlayer insulating film is formed of an oxide film, the etch-stop film is formed of a nitride film.

However, the nitride film can increase the capacitance between the metal lines because it has a high dielectric constant and can increase RC delay accordingly. Consequently, if the distance between the lines is narrowed, it detrimentally effects the operation of the device. The etch-stop film formed of the nitride film cannot reduce the distance between the lines sufficiently.

FIG. 1 is a graph illustrating the relationship between RC delay and a thickness of a nitride film when the nitride film is used as an etch-stop film. In FIG. 1, “A” indicates RC delay by the oxide film, “B” indicates RC delay when the nitride film has a thickness of 100 Å, “C” indicates RC delay when the nitride film has a thickness of 200 Å, and “D” indicates RC delay when the nitride film has a thickness of 300 Å. From FIG. 1, it can be seen that as the thickness of the nitride film increases, RC delay also increases.

### SUMMARY OF THE INVENTION

Disclosed herein is a method of manufacturing a semiconductor device. The method generally includes forming an etch-stop film on a semiconductor substrate in which a predetermined structure is formed and then forming an interlayer insulating film. The method also includes etching a predetermined region of the interlayer insulating film and then stopping the etch process at the etch-stop film. The method results in the formation of a damascene pattern. The etch-stop film is made of a material having a low dielectric constant.

According to an embodiment of the present invention, the method can prevent an increase in the capacitance due to an etch-stop film when a via hole and trenches are etched using a damascene process.

According to another embodiment of the present invention, the an etch-stop film is formed of a material having a dielectric constant lower than that of a nitride film or an interlayer insulating film when etching trenches and a via hole using a damascene process, thereby preventing an increase in the capacitance.

The etch-stop film may be formed any one of amorphous carbon, SiOC, and SiOCH.

The method may further include the step of forming an anti-diffusion film on the damascene pattern, and forming a metal seed layer and a metal layer, thus forming a metal line.

Additional features of the invention may become apparent to those skilled in the art from a review of the following detailed description, taken in conjunction with the drawings, and the appended claims.

### BRIEF DESCRIPTION OF THE DRAWING FIGURES

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a graph illustrating the relationship between RC delay and a thickness of a nitride film when the nitride film is used as an etch-stop film; and,

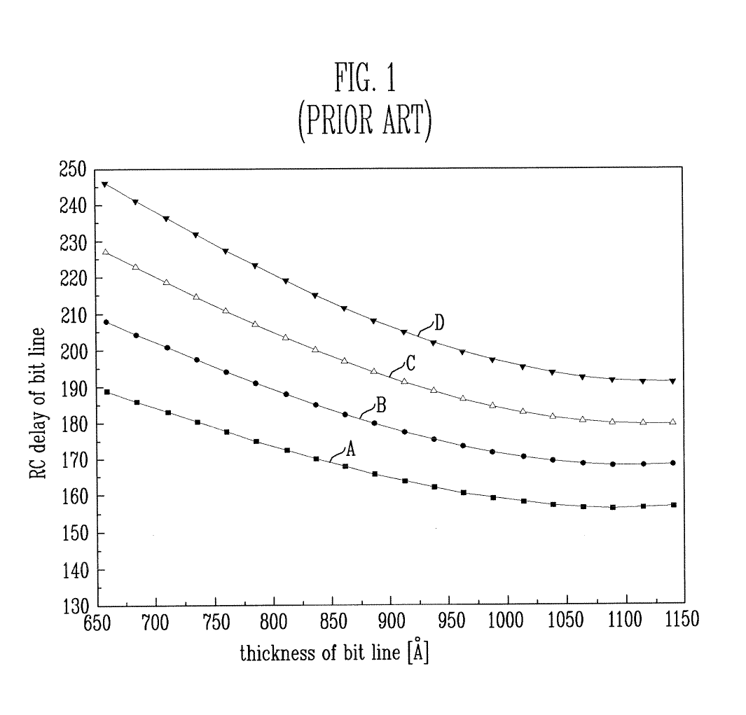

FIGS. 2A to 2C are cross-sectional views illustrating a method of manufacturing a semiconductor device according to an embodiment of the present invention.

While the disclosed method is susceptible of embodiments in various forms, there are illustrated in the drawings (and will hereafter be described) specific embodiments of the method, with the understanding that the disclosure is intended to be illustrative, and is not intended to limit the invention to the specific embodiments described and illustrated herein

### DETAILED DESCRIPTION OF THE INVENTION

The present invention will now be described in detail in connection with certain exemplary embodiments with reference to the accompanying drawings.

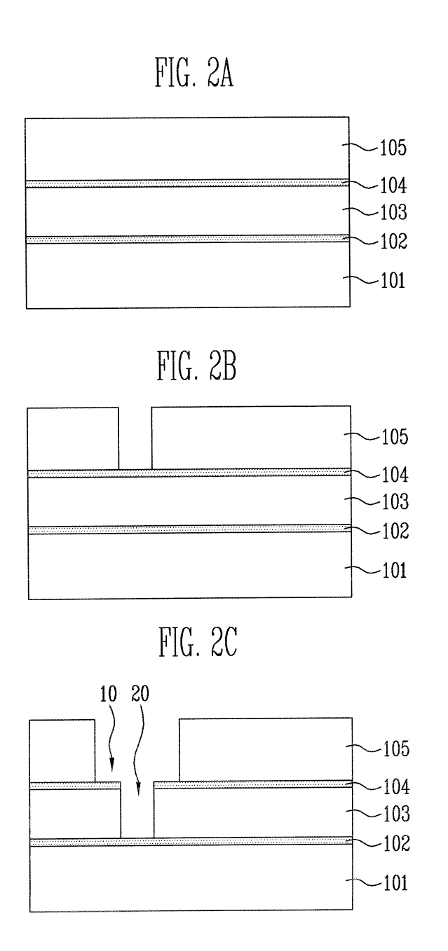

FIGS. 2A to 2C are cross-sectional views illustrating a method of manufacturing a semiconductor device according to an embodiment of the present invention. FIG. 2 illustrates a method of forming copper lines employing the dual damascene method.

Referring to FIG. 2A, a first etch-stop film 102, a first interlayer insulating film 103, a second etch-stop film 104, and a second interlayer insulating film 105 are sequentially formed on a semiconductor substrate 101 in which a predetermined structure is formed.

The first and second etch-stop films 102, 104 may be formed of a material having a dielectric constant lower than that of the existing nitride film (for example, amorphous carbon, SiOC, or SiOCH). Furthermore, the first and second interlayer insulating films 103, 105 may be formed of an oxide-based material. In general, dielectric constants of the known materials will be described below. The oxide film (SiO2) has the dielectric constant of about 4.0, the nitride film has the dielectric constant of about 7.0, amorphous carbon has the dielectric constant of about 2 to 3, and SiOC has the dielectric constant of about 2.5.

Accordingly, the first and second etch-stop films 102, 104 formed using amorphous carbon, SiOC or SiOCH do not increase the capacitance because they have a dielectric constant, which is much lower than that of the nitride film or the first and second interlayer nitride films 103, 105, which is used as the etch-stop film in the related art. Furthermore, a material with a low dielectric constant has an etch selectivity against the oxide film, which is higher than that of the nitride film. For example, amorphous carbon has an etch selectivity against the oxide film, which is three times higher than that of the nitride film, Therefore, there will be no problems in using the material having the low dielectric constant as the etch-stop film.

Referring to FIG. 2B, a predetermined region of the second interlayer insulating film 105 is etched by photo and etch processes employing a via hole mask. The etch process is stopped when the second etch-stop film 104 is exposed.

Referring to FIG. 2C, a predetermined region of the second interlayer insulating film 105 is etched by photo and etch processes employing the trench mask. The etch process is stopped when the second etch-stop film 104 is exposed, thereby forming a trench 10. At the same time, the first interlayer insulating film 103 is etched through the etched portion of the second interlayer insulating film 105, thus forming a via hole 20. Accordingly, a dual damascene pattern including the trench 10 and the via hole 20 is completed.

Thereafter, an anti-diffusion film and a metal seed layer are formed on the entire structure including the trench 10 and the via hole 20. A copper metal layer is formed by an electroplating method so that the trenches 10 and the via hole 20 are buried, thereby forming a metal line.

As described above, according to the present invention, in the process of forming the via hole and the trench by etching the interlayer insulating film by the damascene process, the etch-stop film is formed of a material having a low dielectric constant. Accordingly, an increase in the capacitance due to an etch-stop film formed of the existing material having a high dielectric constant can be prevented. It is therefore possible to prevent a reduction of RC delay and also to accelerate the operating speed of devices.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a semiconductor device, the method comprising the steps of:
forming an etch-stop film on a semiconductor substrate in which a predetermined structure is formed, and then forming an interlayer insulating film; and,
etching a predetermined region of the interlayer insulating film, and then stopping the etch process at the etch-stop film to form a damascene pattern wherein the etch-stop film is a material having a low dielectric constant.

2. The method of claim 1, wherein the etch-stop film is any one of amorphous carbon, SiOC, and SiOCH.

3. The method of claim 1 further comprising the step of forming an anti-diffusion film on the damascene pattern, and forming a metal seed layer and a metal layer to form a metal line.
